(19) United States
(12) Patent Application Publication
(10) Pub. No.: US 2024/0409452 A1
(43) Pub. Date: Dec. 12, 2024

(54) GLASS

(71) Applicant: AGC Inc., Tokyo (JP)

(72) Inventors: Rikiya KADO, Tokyo (JP); Seiji INABA, Tokyo (JP)

(73) Assignee: AGC Inc., Tokyo (JP)

(21) Appl. No.: 18/813,283

(22) Filed: Aug. 23, 2024

Related U.S. Application Data
(63) Continuation of application No. PCT/JP2023/007999, filed on Mar. 3, 2023.

(30) Foreign Application Priority Data
Mar. 8, 2022 (JP) 2022-035417

(51) Int. Cl. C03C 3/091; C03C 3/085; C03C 3/087; H01L 23/15

(52) U.S. Cl. CPC C03C 3/091; C03C 3/085; C03C 3/087; H01L 23/15

(57) ABSTRACT

Rate of thermal expansion is reduced, and also electrical resistance is reduced. A glass 10 has a conductivity parameter A of 1.3 or more, the conductivity parameter A being calculated from the composition and represented by Formula (1), and a thermal expansion parameter B of 2.0 or less, the thermal expansion parameter B being calculated from the composition and represented by Formula (2).

### CROSS-REFERENCE TO RELATED APPLICATION(S)

This application is a continuation of International Application No. PCT/JP2023/007999, filed on Mar. 3, 2023 which claims the benefit of priority of the prior Japanese Patent Application No. 2022-035417, filed on Mar. 8, 2022, the entire contents of which are incorporated herein by reference.

### BACKGROUND OF THE INVENTION

### 1. Field of the Invention

The present invention relates to glass.

### 2. Description of the Related Art

A glass may be used as a member for supporting a semiconductor device during the manufacturing process of the semiconductor device. For example, Japanese Patent No. 6593669 describes a supporting glass substrate having an average coefficient of linear thermal expansion in a temperature range of 20° C. to 200° C. of 50×10⁻⁷/° C. or more and 66×10⁻⁷/° C. or less.

Here, a glass used for applications of supporting a semiconductor device, other applications, and the like is required to have a low electrical resistance while having a low rate of thermal expansion.

### SUMMARY OF THE INVENTION

It is an object of the present invention to at least partially solve the problems in the conventional technology.

The glass of the present disclosure has a conductivity parameter A of 1.3 or more, the conductivity parameter A being calculated from a composition and represented by Formula (1), and a thermal expansion parameter B of 2.0 or less, the thermal expansion parameter B being calculated from the composition and represented by Formula (2).

$$A = [ {R}_{2} O ] / [ {SiO}_{2} ] \times 20 / α \qquad ( 1 )$$

$$B = - 0.12 \times [ {SiO}_{2} ] + 0.3 \times [ {R}_{2} O ] - 0.05 \times [ {Al}_{2} {O}_{3} ] + 8.66 \qquad ( 2 )$$

[R₂O] is a total value of contents of monovalent element oxides contained in the glass in terms of mol % on an oxide basis, [SiO₂] is a content of SiO₂ in terms of mol % on an oxide basis, [Al₂O₃] is a content of Al₂O₃ in terms of mol % on an oxide basis, and a is a value represented by Formula (1A):

$$α = [ {R}_{2} O ] ! / ( [ R {1}_{2} O ] ! \times [ R {2}_{2} O ] ! \times … \times [ {Rn}_{2} O ] ! ) \qquad ( 1 A )$$

Each of [R1₂O], [R2₂O], . . . [Rn₂O] refers to a content of a monovalent element oxide contained in the glass in terms of mol % on an oxide basis.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic diagram of a glass according to the present embodiment; and

FIG. 2 is a schematic diagram illustrating an electrode pattern.

### DETAILED DESCRIPTION OF THE PREFERRED EMBODIMENTS

Hereinafter, preferred embodiments of the present invention will be described in detail with reference to the accompanying drawings. Note that the present invention is not limited by the embodiments, and in a case where there is a plurality of embodiments, the present invention includes a combination of the embodiments. In addition, the numerical value includes the rounding range.

### Glass

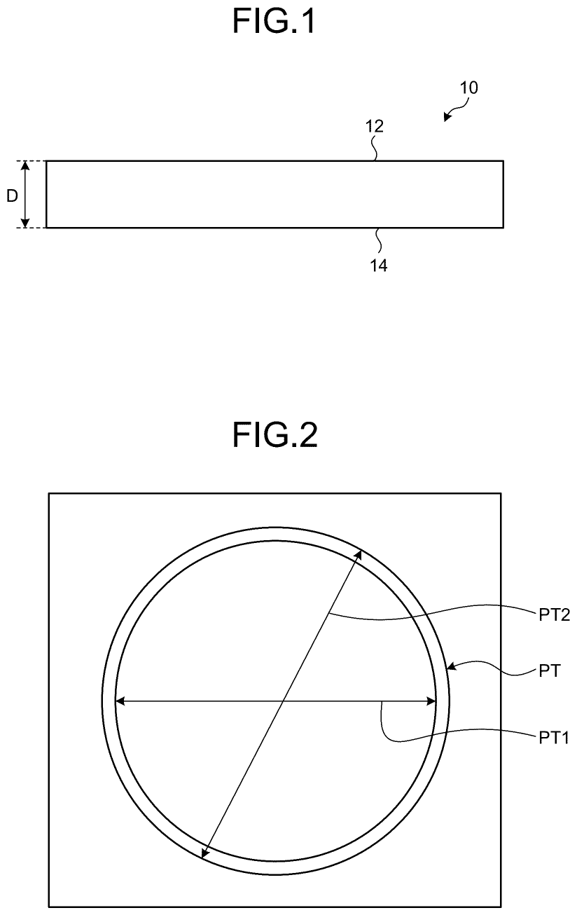

FIG. 1 is a schematic diagram of a glass according to the present embodiment. As illustrated in FIG. 1, the glass 10 according to the present embodiment is used as a glass substrate for manufacturing a semiconductor package, and more specifically, is a supporting glass substrate for manufacturing FOWLP or the like. However, the application of the glass 10 is not limited to the manufacture of FOWLP and the like and may be any application, and the glass 10 may be a glass substrate used for supporting a member or may be used for an application other than the support of a member. Note that FOWLP and the like encompass a fan out wafer level package (FOWLP) and a fan out panel level package (FOPLP).

### Conductivity Parameter

The glass 10 has a conductivity parameter A represented by Formula (1) of 1.3 or more, preferably 1.4 or more and 4.0 or less, more preferably 1.5 or more and 3.0 or less, and still more preferably 1.7 or more and 2.5 or less. The conductivity parameter A can be calculated from the composition of the glass 10. The conductivity parameter A is an index value indicating that the electrical resistance of the glass 10 tends to decrease (the conductivity tends to increase) as its value increases. Thus, the electrical resistance of the glass 10 is low when the conductivity parameter A falls within the above range.

$$A = [ {R}_{2} O ] / [ {SiO}_{2} ] \times 20 / α \qquad ( 1 )$$

Here, [R₂O] in Formula (1) is the total value of the contents of the monovalent element oxides contained in the glass 10 in terms of mol % on an oxide basis. That is, for example, when the glass 10 contains Li₂O, Na₂O, and K₂O, on an oxide basis, [R₂O] can be said to be the total value of the content (mol %) of Li₂O contained in the glass 10, the content (mol %) of Na₂O contained in the glass 10, and the content (mol %) of Na₂O contained in the glass 10 ([Li₂O]+ [Na₂O]+ [K₂O]).

In addition, [SiO₂] in Formula (1) is the content of SiO₂ contained in the glass 10 in terms of mol % on an oxide basis.

In addition, a in Formula (1) is represented by Formula (1A).

$$α = [ {R}_{2} O ] ! / ( [ R {1}_{2} O ] ! \times [ R {2}_{2} O ] ! \times … \times [ {Rn}_{2} O ] ! ) \qquad ( 1 A )$$

Here, [R₂O]! in Formula (1A) refers to the value of the factorial of [R₂O], in other words, the value of the factorial of the total value of the contents of the monovalent element oxides contained in the glass 10 in terms of mol % on an oxide basis. When [R₂O] is not an integer, a value obtained by rounding down decimal places of [R₂O] to an integer may be treated as [R₂O] used for the calculation of [R₂O]!.

For example, when [R₂O] is 6.78 mol %, [R₂O]! becomes 6×5×4×3×2×1 (=720).

In addition, each of [R1₂O], [R2₂O], . . . [Rn₂O] in Formula (1A) refers to the content of each monovalent element oxide contained in the glass 10 in terms of mol % on an oxide basis. That is, it can be said that the ([R120]!×[R2₂O]!×[Rn₂O]!) refers to a value obtained by multiplying the factorial values of the contents of the monovalent element oxides contained in the glass 10 that are determined for each kind of the monovalent element oxides contained in the glass 10. In Formula (1A), the number of kinds of the monovalent element oxides contained in the glass 10 is generalized to n, but the number of kinds of the monovalent element oxides contained in the glass 10 may be any number, and may be 1, 2, or 3 or more.

Also for each of [R1₂O], [R2₂O], . . . [Rn₂O], when the value is not an integer, a value obtained by rounding down decimal places to an integer may be treated as [R1₂O], [R2₂O], . . . [Rn₂O] used for calculation of ([R1₂O]!×[R2₂O]!× . . . ×[Rn₂O]!).

For example, when the glass 10 contains, on an oxide basis, 1.18 mol % of Li₂O, 2.7 mol % of Na₂O, 3.3 mol % of K₂O, and no other monovalent element oxides, the ([R1₂O]!×[R2₂O]!× . . . ×[Rn₂O]!) is 1×2×1×3×2×1 (=12).

Since the conductivity parameter A is a parameter defined as described above, the larger the ratio of the total content of the monovalent element oxides to SiO₂, the higher the value, and the larger the difference between the contents of the different kinds of monovalent element oxides (the unbalanced contents of the monovalent element oxides), the higher the value. In the glass 10 according to the present embodiment, it can be said that the ratio of the total content of the monovalent element oxides to SiO₂ and the balance between the contents of the monovalent element oxides is set such that the conductivity parameter A falls within the above range.

### Thermal Expansion Parameter

The glass 10 has a thermal expansion parameter B represented by Formula (2) of 2.0 or less, preferably 1.74 or less, more preferably 0.1 or more and 1.65 or less, and still more preferably 0.1 or more and 1.55 or less. The thermal expansion parameter B can be calculated from the composition of the glass 10. The thermal expansion parameter B is an index value indicating that the coefficient of thermal expansion of the glass 10 tends to decrease as its value decreases. Thus, the coefficient of thermal expansion of the glass 10 is low when the thermal expansion parameter B falls within the above range.

$$B = - 0.12 \times [ {SiO}_{2} ] + 0.3 \times [ {R}_{2} O ] - 0.05 \times [ {Al}_{2} {O}_{3} ] + 8.66 \qquad ( 2 )$$

Here, [R₂O] in Formula (2) is the total value of the contents of the monovalent element oxides contained in the glass 10 in terms of mol % on an oxide basis, similarly to Formula (1).

In addition, [SiO₂] in Formula (2) is the content of SiO₂ contained in the glass 10 in terms of mol % on an oxide basis, similarly to Formula (1).

In addition, [Al₂O₃] in Formula (2) is the content of Al₂O₃ contained in the glass 10 in terms of mol % on an oxide basis.

Since the thermal expansion parameter B is a parameter defined as described above, the lower the total content of the monovalent element oxides is, the lower the value is, and the higher the content of SiO₂ or Al₂O₃ is, the lower the value is. That is, in the glass 10 according to the present embodiment, it can be said that the total content of the monovalent element oxides and the contents of SiO₂ and Al₂O₃ are set such that the thermal expansion parameter B falls within the above range.

### Composition of Glass

Next, a preferred composition of the glass 10 will be described. However, the glass 10 may have any composition in which the conductivity parameter A and the thermal expansion parameter B satisfy the above ranges.

### SiO₂

The glass 10 preferably contains SiO₂ (the content of SiO₂ is higher than 0 mol %). In the glass 10, the content of SiO₂ is preferably 70.0% or more, more preferably 70.0% or more and 80.0% or less, still more preferably 72.0% or more and 78.0% or less, and even still more preferably 73.5% or more and 75.0% or less as expressed in mol % on an oxide basis. When the content of SiO₂ falls within this range, it is possible to reduce the coefficient of thermal expansion of the glass 10 while reducing the resistance thereof.

B₂O₃

The glass 10 need not contain B₂O₃ (the content of B₂O₃ is 0 mol %), but preferably contains B₂O₃ (the content of B₂O₃ is higher than 0 mol %). In the glass 10, the content of B₂O₃ is preferably 0.1% or more and 15.0% or less, more preferably 0.5% or more and 10.0% or less, and still more preferably 1.0% or more and 5.0% or less as expressed in mol % on an oxide basis. When the content of B₂O₃ falls within this range, it is possible to reduce the coefficient of thermal expansion of the glass 10 while reducing the resistance thereof.

Al₂O₃

The glass 10 need not contain Al₂O₃ (the content of Al₂O₃ is 0 mol %), but preferably contains Al₂O₃ (the content of Al₂O₃ is higher than 0 mol %). In the glass 10, the content of Al₂O₃ is preferably 0.0% or more and 5.0% or less, more preferably 0.1% or more and 3.9% or less, still more preferably 1.0% or more and 3.0% or less, and even still more preferably 0.8% or more and 2.5% or less as expressed in mol % on an oxide basis. When the content of Al₂O₃ falls within this range, it is possible to reduce the coefficient of thermal expansion of the glass 10 while reducing the resistance thereof.

### MgO

The glass 10 need not contain MgO (the content of MgO is 0 mol %), but preferably contains MgO (the content of MgO is higher than 0 mol %). In the glass 10, the content of MgO is preferably 5.0% or more, more preferably 5.0% or more and 15.0% or less, still more preferably 6.3% or more and 14.8% or less, even still more preferably 8.0% or more and 14.6% or less, further preferably 10.0% or more and 14.4% or less, and even further preferably 12.0% or more and 14.2% or less as expressed in mol % on an oxide basis. When the content of MgO falls within this range, it is possible to reduce the coefficient of thermal expansion of the glass 10 while reducing the resistance thereof.

### Cao

The glass 10 need not contain Cao (the content of Cao is 0 mol %), but preferably contains Cao (the content of Cao is higher than 0 mol %). In the glass 10, the content of Cao is preferably 0.0% or more and 20.0% or less, more preferably 0.1% or more and 15.0% or less, still more preferably 0.2% or more and 10.0% or less, and even still more preferably 0.3% or more and 5.0% or less as expressed in molo on an oxide basis. When the content of Cao falls within this range, it is possible to reduce the coefficient of thermal expansion of the glass 10 while reducing the resistance thereof.

### BaO

The glass 10 need not contain BaO (the content of BaO is 0 mol %), but preferably contains BaO (the content of BaO is higher than 0 mol %). In the glass 10, the content of BaO is preferably 0.0% or more and 10.0% or less, more preferably 0.1% or more and 8.0% or less, still more preferably 0.1% or more and 5.0% or less, and even still more preferably 0.1% or more and 3.0% or less as expressed in mol % on an oxide basis. When the content of BaO falls within this range, it is possible to reduce the coefficient of thermal expansion of the glass 10 while reducing the resistance thereof.

### Na₂O

The glass 10 need not contain Na₂O (the content of Na₂O is 0 mol %), but preferably contains Na₂O (the content of Na₂O is higher than 0 mol %). In the glass 10, the content of Na₂O is preferably 0.0% or more and 8.9% or less, more preferably 0.1% or more and 8.0% or less, still more preferably 0.3% or more and 7.0% or less, and even still more preferably 1.0% or more and 6.5% or less as expressed in molo on an oxide basis. When the content of Na₂O falls within this range, it is possible to reduce the coefficient of thermal expansion of the glass 10 while reducing the resistance thereof.

### K₂O

The glass 10 need not contain K₂O (the content of K₂O is 0 mol %), but preferably contains K₂O (the content of K₂O is higher than 0 mol %). In the glass 10, the content of K₂O is preferably 0.0% or more and 8.9% or less, more preferably 0.1% or more and 8.0% or less, still more preferably 0.3% or more and 6.5% or less, and even still more preferably 1.0% or more and 5.5% or less as expressed in mol % on an oxide basis. When the content of K₂O falls within this range, it is possible to reduce the coefficient of thermal expansion of the glass 10 while reducing the resistance thereof.

### SrO

The glass 10 need not contain SrO (the content of SrO is 0 mol %), but preferably contains SrO (the content of SrO is higher than 0 mol %). In the glass 10, the content of SrO is preferably 0.0% or more and 8.9% or less, more preferably 0.1% or more and 7.0% or less, still more preferably 0.15% or more and 5.0% or less, and even still more preferably 0.15% or more and 3.0% or less as expressed in molo on an oxide basis. When the content of SrO falls within this range, it is possible to reduce the coefficient of thermal expansion of the glass 10 while reducing the resistance thereof.

### Li₂O

The glass 10 need not contain Li₂O (the content of Li₂O is 0 mol %), but may contain Li₂O (the content of Li₂O is higher than 0 mol %). When Li₂O is contained in a large amount, vitrification is difficult, and thus it is preferable that Li₂O is not contained in a large amount. In the glass 10, the content of Li₂O is preferably 0.1% or more and 15.0% or less, more preferably 0.3% or more and 10.0% or less, and still more preferably 1.0% or more and 8.0% or less as expressed in mol % on an oxide basis. When the content of Li₂O falls within this range, it is possible to reduce the coefficient of thermal expansion of the glass 10 while reducing the resistance thereof.

### R₂O

The glass 10 need not contain R₂O (the content of R₂O is 0 mol %), but preferably contains R₂O (the content of R₂O is higher than 0 mol %). In the glass 10, the content of R₂O is preferably 0.1% or more and 15.0% or less, more preferably 0.3% or more and 10.0% or less, and still more preferably 1.0% or more and 8.0% or less as expressed in mol % on an oxide basis. When the content of R₂O falls within this range, it is possible to reduce the coefficient of thermal expansion of the glass 10 while reducing the resistance thereof. Note that the content of R₂O refers to the total value of the contents of the monovalent element oxides contained in the glass 10.

Note that the glass 10 preferably does not contain a sintered body. That is, the glass 10 is preferably a glass that is not a sintered body. Here, the sintered body refers to a member in which a plurality of particles is heated at a temperature lower than the melting point to bond the particles. The porosity of the sintered body is high to some extent because the sintered body includes voids, but the porosity of the glass 10 is low, and is usually 0% because the glass is not a sintered body. However, it is allowable to include an inevitable very small amount of pores. The porosity here is a so-called true porosity, and refers to a value obtained by dividing a sum of volumes of pores (voids) communicating with the outside and pores (voids) not communicating with the outside by a total volume (apparent volume). The porosity can be measured according to, for example, JIS R 1634.

In addition, it is preferable that the glass used for the glass 10 is usually an amorphous glass, that is, an amorphous solid. Also, this glass may be a crystallized glass containing crystals on the surface or inside, but an amorphous glass is preferable from the viewpoint of density. Among the ceramics, those produced by a sintering method are preferably not used because they have a low transmittance and a high density.

### Shape of Glass

Next, the shape of the glass 10 will be described. As illustrated in FIG. 1, the glass 10 is a plate-like glass substrate including a first surface 12 that is one surface and a second surface 14 that is the other surface. The second surface 14 is a surface opposite to the first surface 12, and is, for example, parallel to the first surface 12. The glass 10 may have a disk shape that is circular in plan view, that is, when viewed from a direction orthogonal to the first surface 12, but the glass is not limited to the disk shape and may have any shape, and may be a polygonal plate such as a rectangle. Note that examples of the shape also include shapes in which a cut-out such as a notch or an orientation flat is provided on the outer periphery.

In addition, the thickness D of the glass 10, that is, the length between the first surface 12 and the second surface 14 is preferably 0.1 mm to 5.0 mm, more preferably 0.1 mm to 2.0 mm, and still more preferably 0.1 mm to 0.5 mm. By adjusting the thickness D to 0.1 mm or more, it is possible to prevent the glass 10 from becoming too thin and to suppress breakage due to deflection or impact. By adjusting the thickness D to 2.0 mm or less, it is possible to suppress the weight, and by adjusting the thickness D to 0.5 mm or less, it is possible to more suitably suppress the weight.

### Characteristics of Glass

Next, characteristics of the glass 10 will be described.

### Coefficient of Thermal Expansion

The glass 10 has an average coefficient of thermal expansion CTE at 50° C. to 200° C. of preferably 6.0 ppm/° C. or less, more preferably 3.0 ppm/° C. or more and 5.5 ppm/° C. or less, and still more preferably 3.0 ppm/° C. or more and 5.3 ppm/° C. or less. When the average coefficient of thermal expansion CTE falls within this range, the glass 10 has low thermal expansion and thus breakage can be suppressed. Note that the average coefficient of thermal expansion CTE can be measured in accordance with DIN-51045-1 as a standard for thermal expansion measurement. Specifically, a sample is measured in a range of 30° C. to 300° C. using a dilatometer (DIL 402 Expedis) of NETZSCH as a measuring apparatus, and an average coefficient of thermal expansion in the range of 50° C. to 200° C. may be defined as the average coefficient of thermal expansion CTE.

### Resistivity

When the resistivity of the glass 10 at 250° C. is defined as p Ω·cm, log p=8.0 or less is preferable, log p=7.5 or less is more preferable, and log p=7.0 or less is still more preferable. When the resistivity falls within this range, electrical resistance can be reduced. Note that the resistivity at 250° C. can be measured by a high-temperature volume resistance measuring apparatus.

### (Young's Modulus)

The glass 10 preferably has a Young's modulus of 65 GPa or more, more preferably 70 GPa or more. When the Young's modulus falls within this range, breakage can be suppressed. The Young's modulus of the glass 10 can be measured based on propagation of an ultrasonic wave using 38DL PLUS manufactured by Olympus Corporation.

### Acid Resistance

The glass 10 preferably has acid resistance. The glass 10 preferably passes the evaluation of acid resistance defined in the examples described later. When the glass 10 has acid resistance, it is particularly preferable as, for example, a supporting glass substrate.

### UV Transmittance

The glass 10 preferably has a transmittance of light (ultraviolet ray) having a wavelength of 308 nm, that is, a UV transmittance of 50% or more, and more preferably 70% or more. When the transmittance of light having a wavelength of 308 nm falls within this range, ultraviolet rays are appropriately transmitted, and thus it is particularly preferable as a support glass substrate. Note that the transmittance of light having a wavelength of 308 nm can be measured by measuring a spectral transmittance curve using, for example, an ultraviolet-visible spectrophotometer (UH4150 type, manufactured by Hitachi High-Tech Corporation).

### Hopping Frequency

In the glass 10, log op, which is the logarithm of the hopping frequency op, is preferably 2.0 or more and 6.0 or less, and more preferably 3.0 or more and 5.0 or less. When the hopping frequency falls within this range, ease of vitrification is not deteriorated and the glass is less likely to be charged.

Note that the hopping frequency is measured as follows. FIG. 2 is a schematic diagram illustrating an electrode pattern. A glass plate is processed into a plate shape of 50 mm×50 mm×0.7 mm, and an electrode pattern PT illustrated in FIG. 2 is formed on one surface. As illustrated in FIG. 2, the electrode pattern PT has an annular shape with an inner diameter PT1 of 38 mm and an outer diameter PT2 of 40 mm. The impedance at 20 MHz to 2 MHz is measured using an impedance analyzer to determine the complex admittance. With the coefficients K=−11.066, n1=0.992, n2=0.651, and C∞=20.407 in the model equation of the complex admittance Y*(ω) related to ion conductive materials (Journal of Materials Science vol. 19, p3236), op is calculated from Formula (1) and the obtained complex admittance. Note that A1, B1, A2, and B2 in Formula (1) are values represented by Formulae (2) to (5).

$${Y}^{*} ( ω ) = {A}_{1} {ω}^{{n}_{1}} + {A}_{2} {ω}^{{n}_{2}} + i ( {B}_{1} {ω}^{{n}_{1}} + {B}_{2} {ω}^{{n}_{2}} ) + i ω {C}_{∞} \qquad ( 1 )$$

$${A}_{1} = K {ω}_{p}^{1 - {n}_{1}} \qquad ( 2 )$$

$${B}_{1} = {A}_{1} tan ( {n}_{1} π / 2 ) \qquad ( 3 )$$

$${A}_{2} = K {ω}_{p}^{1 - {n}_{2}} \qquad ( 4 )$$

$${B}_{2} = {A}_{2} tan ( {n}_{2} π / 2 ) \qquad ( 5 )$$

### Method for Manufacturing Glass

The glass 10 may be manufactured by any method, but is manufactured, for example, by the following method. First, a raw material such as silica sand or soda ash, which is a raw material of the compound contained in the glass 10, is melted by heating at a predetermined temperature (for example, 1500° C. to 1600° C.). Then, after the melted raw material (glass) is clarified, a molding step of molding the raw material into a plate shape is performed. The formed glass has the composition range of the glass 10 described above on an oxide basis. Then, a slow cooling step is performed on the glass molded in the molding step to manufacture glass 10.

Note that the method for manufacturing the glass 10 is not limited to the above, and may be any method. For example, the slow cooling step is not essential. In addition, various methods can be adopted as the molding step in manufacturing the glass 10, and examples thereof include a melt casting method, down-draw methods (for example, an overflow down-draw method, a slot down method, a redraw method, and the like), a float method, a roll-out method, and a press method.

Next, an example of a manufacturing step performed when the glass 10 is used for FOWLP manufacturing will be described. In the FOWLP manufacturing, a plurality of semiconductor chips is bonded onto the glass 10, and the semiconductor chips are covered with an encapsulant to form an element substrate. Then, the glass 10 and the element substrate are separated, and the opposite side of the element substrate from the semiconductor chips is bonded onto, for example, another glass 10. Then, wiring, solder bumps, and the like are formed on the semiconductor chips, and the element substrate and the glass 10 are separated again. Then, the element substrate is cut into pieces for each semiconductor chip, thereby obtaining a semiconductor device.

### Effects

As described above, the glass 10 according to the present embodiment has the conductivity parameter A of 1.3 or more and the thermal expansion parameter B of 2.0 or less.

Here, there is a case where a glass is required to have a low electrical resistance while having a low rate of thermal expansion. Regarding that, since the glass 10 according to the present embodiment has a conductivity parameter A and a thermal expansion parameter B that fall within the above ranges, it is possible to reduce the electrical resistance while reducing the coefficient of thermal expansion. In particular, for example, when a glass is used to support a semiconductor device, it is required to suppress deflection at high temperature and to be less likely to be charged. Regarding that, since the conductivity parameter A of the glass 10 according to the present embodiment falls within the above range, the glass has low resistance and is less likely to be charged, and since the thermal expansion parameter B thereof falls within the above range, the coefficient of thermal expansion is reduced and thus deflection at high temperature can be suppressed.

Furthermore, there is a case where a glass is required to have acid resistance. Regarding that, since the thermal expansion parameter B of the glass 10 according to the present embodiment falls within the above range, acid resistance can also be realized.

Note that a glass tends to have higher conductivity (lower resistance) as the amounts of the monovalent element oxides increase, but when the amounts of the monovalent element oxides increase, the amount of the component contributing to low thermal expansion, for example, such as SiO₂, relatively decreases, whereby the coefficient of thermal expansion tends to increase. That is, it can be said that there is a trade-off relationship between the conductivity (low resistance) property and the low thermal expansion property. Regarding that, in the glass 10 according to the present embodiment, the contents of the monovalent element oxides, SiO₂, and Al₂O₃, and the like are set such that the conductivity parameter A is 1.3 or more and also the thermal expansion parameter B is 2.0 or less. Thus, the glass 10 according to the present embodiment can achieve both low resistance and low thermal expansion by balancing the low resistance property and the low thermal expansion property.

The glass 10 preferably has a thermal expansion parameter B of 1.74 or less. When the thermal expansion parameter B falls within this range, the coefficient of thermal expansion can be more suitably reduced.

The glass 10 preferably contains B₂O₃. When it contains B₂O₃, the coefficient of thermal expansion is reduced, and also the electrical resistance can be reduced.

The glass 10 preferably contains MgO. When it contains MgO, the coefficient of thermal expansion is reduced, and also the electrical resistance can be reduced.

The glass 10 preferably has a MgO content of 5.0% or more in terms of mol % on an oxide basis. When the content of MgO falls within this range, it is possible to reduce the electrical resistance while reducing the coefficient of thermal expansion.

The glass 10 preferably has a SiO₂ content of 70.0% or more in terms of mol % on an oxide basis. When the content of SiO₂ falls within this range, it is possible to reduce the electrical resistance while reducing the coefficient of thermal expansion.

The glass 10 preferably contains
SiO₂: 70.0% to 80.0%,
B₂O₃: 0.1% to 15.0%,
Al₂O₃: 0.0% to 5.0%,
MgO: 5.0% to 15.0%,
CaO: 0% to 20%,
BaO: 0% to 10%,
Na₂O: 0% to 8.9%,
K₂O: 0% to 8.9%, and
SrO: 0% to 10%

as expressed in mol % on an oxide basis. When the content of each component falls within this range, it is possible to reduce the electrical resistance while reducing the coefficient of thermal expansion. Note that a numerical range represented by “to” means a numerical range including numerical values before and after “to” as a lower limit value and an upper limit value, and when “to” is used in the following description, the same meaning is given.

The glass 10 preferably has an average coefficient of thermal expansion CTE at 50° C. to 200° C. of 6.0 ppm/° C. or less and a resistivity at 250° C. of 8.0 Ω·cm-1 or less. When the average coefficient of thermal expansion and the resistivity fall within these ranges, it is possible to reduce the electrical resistance while reducing the coefficient of thermal expansion.

The glass 10 is preferably an amorphous glass. When the glass is an amorphous glass, it is possible to reduce the electrical resistance while reducing the coefficient of thermal expansion.

The glass 10 is preferably used as a substrate, and is preferably used for manufacturing at least one of a fan out wafer level package or a fan out panel level package. The glass 10 is suitably used for these applications.

### EXAMPLES

Next, examples will be described. Note that the embodiment may be changed as long as the effect of the invention is obtained.

In the examples, glasses having different compositions were produced. In the examples, a base plate having a diameter of 320 mm and a thickness of 6 mm was manufactured using a melt casting method. Next, a plurality of plates having a diameter of 300 mm and a thickness of 3 mm was cut out from the center of the base plate. Both surfaces of these plates were polished using cerium oxide as a polishing material to obtain glasses.

Table 1 shows the properties of the glass of each example. Table 1 shows the contents, expressed in mol % on an oxide basis, of the materials used for producing the glass, the conductivity parameters A, and the thermal expansion parameters B for Examples 1 to 14 and Examples 15 to 21. The conductivity parameter A and the thermal expansion parameter B were calculated by the method described in the above embodiment.

TABLE 1

| | | Exam- | Exam- | Exam- | Exam- | Exam- | Exam- | Exam- | Exam- | Exam- | Exam- | Exam- |
|---|---|---|---|---|---|---|---|---|---|---|---|---|
| | | ple 1 | ple 2 | ple 3 | ple 4 | ple 5 | ple 6 | ple 7 | ple 8 | ple 9 | ple 10 | ple 11 |
| Composition | SᵢO₂ | 77.5 | 73.9 | 75.1 | 73.9 | 74.6 | 74.4 | 52.7 | 51.9 | 66.1 | 73.9 | 60 |
| (mol %) | B₂O₃ | 0.9 | 4.4 | 2.9 | 3.6 | 2.7 | 5.1 | | 7.7 | 7.8 | 0.9 | |
| | Al₂O₃ | 1.7 | 1.7 | 1.7 | 1.7 | 1.7 | 2.2 | 12 | 16.3 | 11.3 | 1.7 | 4 |
| | MgO | 13.9 | 13.9 | 13.9 | 13.9 | 13.9 | 12 | 21.2 | 10.5 | 5.1 | 13.9 | 5 |
| | CaO | 0.3 | 0.3 | 0.3 | 0.3 | 0.3 | 1.0 | 14.1 | 10.8 | 4.5 | 0.3 | |
| | SrO | 0.2 | 0.2 | 0.2 | 0.2 | 0.2 | | | | | 0.2 | 5 |
| | BaO | 0.1 | 0.1 | 0.1 | 0.1 | 0.1 | | | | | 0.1 | 6 |
| | Li₂O | | | | | | | | | | | |
| | Na₂O | 5.4 | 5.5 | 5.8 | 6.3 | 6.4 | 0.1 | | 2.8 | | 9 | 10 |
| | K₂O | | | | | | 5.2 | | | | | 10 |

| | | | | | | | | | | | |
|---|---|---|---|---|---|---|---|---|---|---|---|
| Conductivity | 1.38 | 1.48 | 1.53 | 1.71 | 1.72 | 1.43 | 0 | 1.08 | 0 | 2.43 | 0 |
| parameter A | | | | | | | | | | | |
| Thermal expansion | 0.89 | 1.35 | 1.29 | 1.61 | 1.52 | 1.21 | 1.96 | 2.46 | 0.16 | 2.4 | 7.26 |
| parameter B | | | | | | | | | | | |
| Average coefficient | 4.59 | 4.77 | 4.83 | 5.05 | 5.10 | 5.00 | 5.1 | 4.76 | 3.63 | 6.1 | 12.07 |
| of thermal expansion | | | | | | | | | | | |
| @ 50° C. to 200° C. | | | | | | | | | | | |
| (ppm/° C.) | | | | | | | | | | | |
| Resistivity @ | 6.9 | 7.1 | 6.9 | 6.9 | 6.8 | 7.4 | 14 | 9.4 | 13.2 | 6.5 | 9.1 |
| 250° C. (Ω · cm⁻¹) | | | | | | | | | | | |
| Young's modulus | 76 | 76 | 76 | 75 | 76 | 76 | 82 | 89 | 76 | 76 | |
| Acid resistance | ◯ | ◯ | ◯ | ◯ | ◯ | ◯ | X | X | ◯ | ◯ | X |
| UV transmittance @ | — | — | — | 83.3 | 88.8 | — | 37 | — | — | — | — |
| 1 mmt, 308 nm (%) | | | | | | | | | | | |
| Hopping frequency | 3.93 | 2.95 | 3.35 | 3.43 | 3.78 | — | −23.4 | — | −60 | — | — |

| | | Exam- | Exam- | Exam- | Exam- | Exam- | Exam- | Exam- | Exam- | Exam- | Exam- |
|---|---|---|---|---|---|---|---|---|---|---|---|
| | | ple 12 | ple 13 | ple 14 | ple 15 | ple 16 | ple 17 | ple 18 | ple 19 | ple 20 | ple 21 |
| Composition | SᵢO₂ | 65.2 | 63.2 | 71.5 | 71 | 75 | 74 | 74 | 74 | 76.1 | 74.5 |
| (mol %) | B₂O₃ | | | | 1.9 | 2 | 3.5 | 4 | 3.5 | 1.8 | 3.3 |
| | Al₂O₃ | 11.6 | 11.3 | 2.3 | 7.2 | 4 | 1.8 | 1.3 | 1.8 | 1.7 | 1.7 |
| | MgO | 11.8 | 11.3 | 14.9 | 13.9 | 8 | 2 | 2 | 2 | 13.9 | 13.9 |
| | CaO | 6.4 | 6.2 | | 0.3 | 2 | 10.2 | 10.2 | 6.2 | 0.3 | 0.3 |
| | SrO | | 3 | | 0.2 | 2 | | | 4 | 0.2 | 0.2 |
| | BaO | | | | 0.1 | 2 | 2 | 2 | 2 | 0.1 | 0.1 |
| | Li₂O | | | | | | | | | | |
| | Na₂O | 2 | 2 | 11.3 | 5.4 | 5 | 6.5 | 6.5 | 6.5 | 5.9 | 6 |
| | K₂O | 3 | 3 | | | | | | | | |

| | | | | | | | | | | |
|---|---|---|---|---|---|---|---|---|---|---|
| Conductivity | 0.15 | 0.16 | 3.16 | 1.52 | 1.33 | 1.76 | 1.76 | 1.76 | 1.55 | 1.61 |
| parameter A | | | | | | | | | | |
| Thermal expansion | 1.76 | 2 | 3.36 | 1.4 | 0.96 | 1.64 | 1.67 | 1.64 | 1.21 | 1.44 |
| parameter B | | | | | | | | | | |
| Average coefficient | 5.16 | 5.78 | 7.8 | (4.58) | (4.86) | (5.74) | (5.76) | (5.9) | (4.85) | (4.94) |
| of thermal expansion | | | | | | | | | | |
| @ 50° C. to 200° C. | | | | | | | | | | |
| (ppm/° C.) | | | | | | | | | | |
| Resistivity @ | 9.3 | 9.7 | 7 | (7.2) | (7.5) | (7.8) | (7.9) | (8) | (6.9) | (6.9) |
| 250° C. (Ω · cm⁻¹) | | | | | | | | | | |
| Young's modulus | 85 | 84 | 78 | (78) | (71) | (64) | (63) | (64) | (76) | (76) |
| Acid resistance | ◯ | ◯ | ◯ | ◯ | ◯ | ◯ | ◯ | ◯ | ◯ | ◯ |
| UV transmittance @ | — | — | — | — | — | — | — | — | — | — |
| 1 mmt, 308 nm (%) | | | | | | | | | | |
| Hopping frequency | — | — | — | — | — | — | — | — | — | — |

The coefficient of thermal expansion and the resistivity of the glass of each example were evaluated.

In the evaluation of the coefficient of thermal expansion, the average coefficient of thermal expansion CTE at 50° C. to 200° C. was measured. The average coefficient of thermal expansion CTE at 50° C. to 200° C. was measured by a dilatometer (DIL 402 Expedis) of NETZSCH. In the evaluation of the resistivity, the resistivity p at 250° C. was measured, and the log p was calculated. The resistivity at 250° C. was measured by a high-temperature volume resistance measuring apparatus. The measured values are shown in Table 1. Note that the bracketed values in the table are obtained by calculation.

For the glass of each example, when the glass had an average coefficient of thermal expansion CTE at 50° C. to 200° C. of 6.0 ppm/° C. or less and a resistivity at 250° C. of 8.0 Ω·cm-1 or less, it was determined as pass, and when the glass did not satisfy at least one of these conditions, it was determined as fail.

The glasses of Examples 1 to 6 and Examples 15 to 21 according to the examples in which the conductivity parameter A is 1.3 or more and the thermal expansion parameter B is 2.0 or less pass, and it can be seen that it is possible to reduce the electrical resistance while reducing the coefficient of thermal expansion. On the other hand, the glasses of Examples 7 to 14 according to the comparative examples in which at least one of the conductivity parameter A of 1.3 or more or the thermal expansion parameter B of 2.0 or less is not satisfied fail, and it can be seen that it is not possible to reduce the electrical resistance while reducing the coefficient of thermal expansion.

As an optional evaluation, Young's modulus, acid resistance, UV transmittance, and hopping frequency were measured.

The Young's modulus was measured based on propagation of an ultrasonic wave using 38DL PLUS manufactured by Olympus Corporation.

For the acid resistance, the glass was immersed for 20 hours in 0.1 mol % hydrochloric acid held at 90° C., and the ratio of the weight decreased after immersion in hydrochloric acid to the weight before immersion was calculated. A case where the ratio was 0.1% or more was determined as pass, and a case where the ratio was less than 0.1% was determined as fail.

The UV transmittance refers to the transmittance of light (ultraviolet ray) at a wavelength of 308 nm. The UV transmittance was measured by measuring a spectral transmittance curve using an ultraviolet-visible spectrophotometer (UH4150 type, manufactured by Hitachi High-Tech Corporation).

For the hopping frequency, the electrode pattern of FIG. 2 was formed on a glass plate of 50 mm×50 mm×0.7 mm, and the complex admittance was measured by the method described in the above embodiment using an impedance analyzer (precision LCR meter E4980A and 16451B dielectric test fixture with attached electrodes A manufactured by Keysight Technologies). The hopping frequency op was calculated from the obtained complex admittance value, and log op, which is the logarithm of the hopping frequency ωp, was calculated.

The measurement results are shown in Table 1.

The present invention can reduce electrical resistance while reducing rate of thermal expansion.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A glass having a conductivity parameter A of 1.3 or more, the conductivity parameter A being calculated from a composition and represented by Formula (1), and a thermal expansion parameter B of 2.0 or less, the thermal expansion parameter B being calculated from the composition and represented by Formula (2),
$$A = [ {R}_{2} O ] / [ {SiO}_{2} ] \times 20 / α \qquad ( 1 )$$
$$B = - 0.12 \times [ {SiO}_{2} ] + 0.3 \times [ {R}_{2} O ] - 0.05 \times [ {Al}_{2} {O}_{3} ] + 8.66 \qquad ( 2 )$$
wherein
[R₂O] is a total value of contents of monovalent element oxides contained in the glass in terms of mol % on an oxide basis,
[SiO₂] is a content of SiO₂ in terms of mol % on an oxide basis,
[Al₂O₃] is a content of Al₂O₃ in terms of mol % on an oxide basis, and
a is a value represented by Formula (1A):
$$α = [ {R}_{2} O ] ! / ( [ R {1}_{2} O ] ! \times [ R {2}_{2} O ] ! \times … \times [ {Rn}_{2} O ] ! ) \qquad ( 1 A )$$
wherein each of [R1₂O], [R2₂O], . . . [Rn₂O] refers to a content of a monovalent element oxide contained in the glass in terms of mol % on an oxide basis.

2. The glass according to claim 1, wherein the thermal expansion parameter B is 1.74 or less.

3. The glass according to claim 1, comprising B₂O₃.

4. The glass according to claim 1, comprising MgO.

5. The glass according to claim 4, wherein a content of MgO in terms of mol % on an oxide basis is 5.0% or more.

6. The glass according to claim 5, wherein the content of MgO in terms of mol % on an oxide basis is 10.0% or more.

7. The glass according to claim 1, wherein the content of SiO₂ in terms of mol % on an oxide basis is 70.0% or more.

8. The glass according to claim 1, comprising:
SiO₂: 70.0% to 80.0%,
B₂O₃: 0.1% to 15.0%,
Al₂O₃: 0.0% to 5.0%,
MgO: 5.0% to 15.0%,
CaO: 0.0% to 20.0%,
BaO: 0.0% to 10.0%,
Na₂O: 0.0% to 8.9%,
K₂O: 0.0% to 8.9%, and
SrO: 0.0% to 8.9%
as expressed in mol % on an oxide basis.

9. The glass according to claim 1, wherein an average coefficient of thermal expansion CTE at 50° C. to 200° C. is 6.0 ppm/° C. or less, and a resistivity at 250° C. is 8.0 Ω·cm-1 or less.

10. The glass according to claim 1, which is an amorphous glass.

11. The glass according to claim 1, which is used as a substrate.

12. The glass according to claim 11, which is used in manufacture of at least one of a fan out wafer level package or a fan out panel level package.
